(19) United States
(12) Patent Application Publication
(10) Pub. No.: US 2023/0097227 A1
(43) Pub. Date: Mar. 30, 2023

(54) SEMICONDUCTOR DEVICE AND METHOD OF MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kentaro MORI, Fujisawa Kanagawa (JP); Kazushiro NOMURA, Kawasaki Kanagawa (JP); Kenichi OHASHI, Kawasaki Kanagawa (JP); Soichi YAMASHITA, Kawasaki Kanagawa (JP); Aya MURAYOSHI, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/690,399

(22) Filed: Mar. 9, 2022

(30) Foreign Application Priority Data
Sep. 22, 2021 (JP) 2021-154482

(51) Int. Cl. H01L 21/784; H01L 29/417; H01L 29/40

(52) U.S. Cl. CPC H01L 21/784; H01L 29/401; H01L 29/41741

(57) ABSTRACT

A semiconductor device includes: a semiconductor chip having a bottom surface having a first area and a first side surface; and an electrode provided below the semiconductor chip, the electrode having a first top surface and a second side surface, and the electrode containing an electrically conductive material, wherein the first top surface has a second area larger than the first area, and at least a part of the first top surface is in contact with the bottom surface.

### CROSS-REFERENCE TO RELATED APPLICATION

This application is based upon and claims the benefit of priority from Japanese Patent Application No. 2021-154482, filed on Sep. 22, 2021, the entire contents of which are incorporated herein by reference.

### FIELD

Embodiments described herein relate generally to a semiconductor device.

### BACKGROUND

Semiconductor devices, such as a metal oxide semiconductor field effect transistor (MOSFET), are used in applications such as power conversion. Such a semiconductor device is formed on a semiconductor wafer and then separated into individual chips by a predetermined dicing process.

### BRIEF DESCRIPTION OF THE DRAWINGS

FIG. 1 is a schematic cross-sectional view of a semiconductor device of a first embodiment;

FIGS. 2A to 2E are schematic cross-sectional views showing a process of manufacturing the semiconductor device of the first embodiment;

FIG. 3 is a schematic cross-sectional view of a semiconductor device of a second embodiment;

FIGS. 4A to 4E are schematic cross-sectional views showing a process of manufacturing the semiconductor device of the second embodiment;

FIG. 5 is a schematic cross-sectional view of a semiconductor device of a third embodiment;

FIGS. 6A to 6D are schematic cross-sectional views showing a process of manufacturing the semiconductor device of the third embodiment;

FIG. 7 is a schematic cross-sectional view of a semiconductor device of a fourth embodiment;

FIGS. 8A to 8D are schematic cross-sectional views showing a process of manufacturing the semiconductor device of the fourth embodiment;

FIG. 9 is a schematic cross-sectional view of a semiconductor device of a fifth embodiment; and

FIGS. 10A to 10D are schematic cross-sectional views showing a process of manufacturing the semiconductor device of the fifth embodiment.

### DETAILED DESCRIPTION

A semiconductor device of embodiments includes: a semiconductor chip having a bottom surface having a first area and a first side surface; and an electrode provided below the semiconductor chip, the electrode having a first top surface and a second side surface, and the electrode containing an electrically conductive material, wherein the first top surface has a second area larger than the first area, and at least a part of the first top surface is in contact with the bottom surface.

Hereinafter, embodiments will be described with reference to the diagrams. In the following description, the same members and the like are denoted by the same reference numerals, and the description of the members and the like once described will be omitted as appropriate.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

### First Embodiment

A semiconductor device of embodiments includes: a semiconductor chip having a bottom surface having a first area and a first side surface; and an electrode provided below the semiconductor chip, the electrode having a first top surface and a second side surface, and the electrode containing an electrically conductive material, wherein the first top surface has a second area larger than the first area, and at least a part of the first top surface is in contact with the bottom surface.

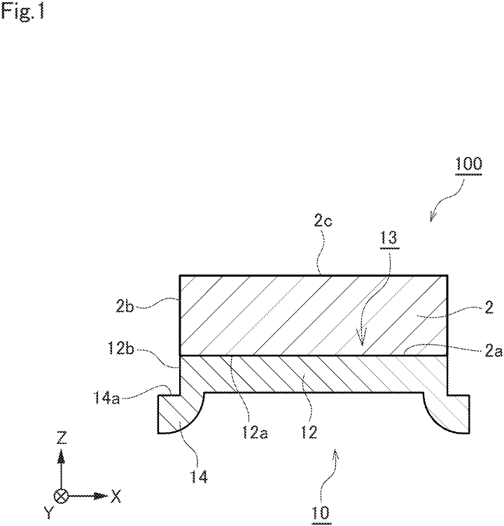

FIG. 1 is a schematic cross-sectional view of a semiconductor device 100 of embodiments. The semiconductor device 100 of embodiments is, for example, a MOSFET or an insulated gate bipolar transistor (IGBT).

A semiconductor chip 2 has a bottom surface 2a, a first side surface 2b (a side surface of the semiconductor chip; an example of the side surface), and a top surface 2c. The area of the bottom surface 2a is the first area S₁. The semiconductor chip 2 includes a semiconductor material. Here, examples of the semiconductor material include silicon (Si), silicon carbide (SiC), gallium arsenide (GaAs), and gallium nitride (GaN). However, the semiconductor material is not limited to these. For example, a MOSFET device or an IGBT device is formed on the top surface 2c. When a MOSFET device is formed, for example, a source electrode or a gate electrode (not shown) of the MOSFET is provided on the top surface 2c.

An electrode 10 is provided below the semiconductor chip 2 and is in contact with the bottom surface 2a. For example, when the semiconductor chip 2 is a MOSFET chip, the electrode 10 is a drain electrode of the MOSFET. The electrode 10 has a first top surface 13. The electrode 10 has a first portion 12 and a second portion 14. The first portion 12 is in contact with the bottom surface 2a. The first portion 12 has a second top surface 12a and a second side surface 12b (a side surface of the electrode). The second portion 14 has a third top surface 14a. In other words, the first top surface 13 has the second top surface 12a and the third top surface 14a. The second portion 14 is connected to the end of the first portion 12. The second portion 14 is provided diagonally downward with respect to the semiconductor chip 2. The sum of the area of the second top surface 12a of the first portion 12 and the area of the third top surface 14a of the second portion 14 is the second area S₂ of the first top surface 13 of the electrode 10. The second area S₂ is larger than the first area S₁. For example, the area of the second top surface 12a of the first portion 12 is equal to the first area S₁ of the bottom surface 2a of the semiconductor chip 2. The electrode 10 contains an electrically conductive material. Here, examples of the electrically conductive material include copper (Cu), aluminum (Al), nickel (Ni), silver (Ag), and gold (Au). However, the electrically conductive material is not limited to these.

Here, an X direction, a Y direction perpendicular to the X direction, and a Z direction perpendicular to the X and Y directions are defined. It is assumed that the bottom surface 2a is provided in parallel to the XY plane.

As a modification example of embodiments, in a region above the third top surface 14a of the second portion 14, a resin such as an adhesive 52, which will be described later, may be left (provided) so as to cover the first side surface 2b and the second side surface 12b (so as to be in contact with the first side surface 2b, the second side surface 12b, and the third top surface 14a).

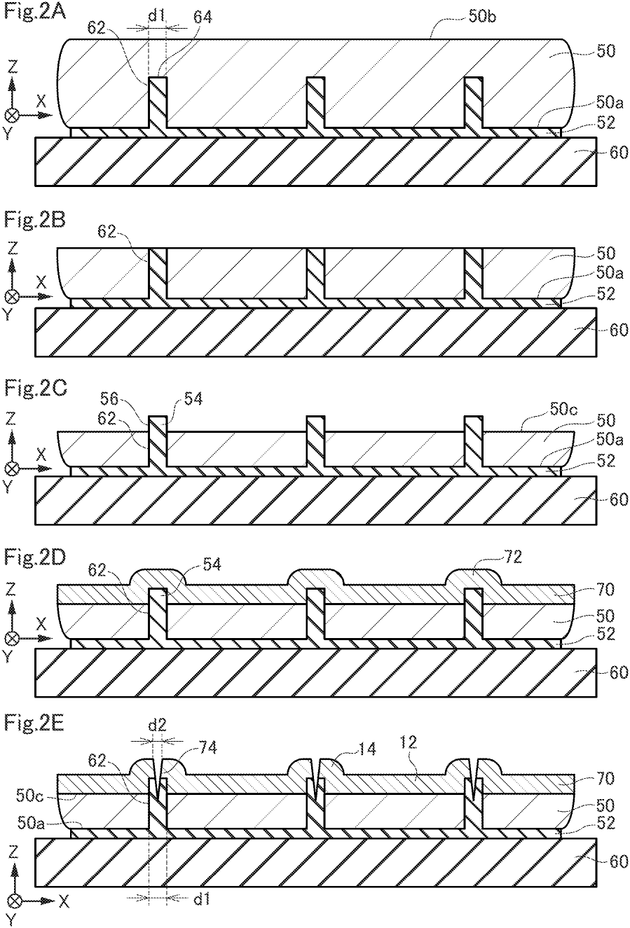

FIGS. 2A to 2E are schematic cross-sectional views showing a process of manufacturing the semiconductor device 100 of embodiments.

A method of manufacturing a semiconductor device of embodiments includes: forming a first groove not penetrating a semiconductor substrate in the semiconductor substrate from a side of a first surface of the semiconductor substrate having the first surface and a second surface; forming a third surface of the semiconductor substrate by removing a part of the semiconductor substrate on a side of the second surface so that the first groove is exposed; forming a film containing an electrically conductive material on the third surface; and removing a part of the film formed adjacent to the first groove with a width smaller than the width of the first groove.

A semiconductor substrate 50 has a first surface 50a and a second surface 50b. For example, a MOSFET device or an IGBT device is formed on the first surface 50a. The electrode 10 is formed on the second surface 50b after being ground, as will be described later.

The semiconductor substrate 50 contains a semiconductor material. Here, examples of the semiconductor material include silicon (Si), silicon carbide (SiC), gallium arsenide (GaAs), and gallium nitride (GaN). However, the semiconductor material is not limited to these.

A first groove 62 (an example of a groove) that does not penetrate the semiconductor substrate 50 is formed in the semiconductor substrate 50 from the side of the first surface 50a of the semiconductor substrate 50. The first groove 62 has a bottom portion 64. In addition, the first groove 62 has a width d₁. When forming the first groove 62, blade dicing using a blade may be used. In addition, when forming the first groove 62, laser dicing using a laser may be used. In addition, when forming the first groove 62, plasma dicing may be used. The plasma dicing herein is dicing performed, for example, by repeating isotropic etching using fluorine (F)-based radicals, formation of a protective film containing carbon tetrafluoride (CF₄)-based radicals, and anisotropic etching using F-based ions.

In addition, the first groove 62 is formed in parallel to the Y direction. However, a grid-like first groove 62 may be further formed in parallel to the X direction.

Then, the adhesive 52 is applied to the first surface 50a and the first groove 62 so as to be filled up to the bottom portion 64 of the first groove 62. As the adhesive 52, for example, an acrylic adhesive, an epoxy adhesive, or a silicone adhesive can be preferably used.

Then, the semiconductor substrate 50 is fixed to a substrate 60 by using the adhesive 52. The substrate 60 is a support substrate formed of, for example, glass. The semiconductor substrate 50 is fixed onto the substrate 60 by using the adhesive 52 so that the substrate surface of the substrate 60 is parallel to the first surface 50a and the second surface 50b (FIG. 2A).

Then, a part of the semiconductor substrate 50 on the side of the second surface 50b is removed by, for example, grinding to expose the first groove 62 (FIG. 2B).

Then, a part of the semiconductor substrate 50 is removed by, for example, wet etching to form a third surface 50c on the semiconductor substrate 50. As a result, a part of a third side surface 56 (a side surface of the adhesive; an example of the side surface) and an upper portion 54 of the adhesive 52 are exposed to protrude above the third surface 50c (FIG. 2C).

Then, the film 70 containing an electrically conductive material is formed on the third surface 50c and the adhesive 52 by, for example, chemical vapor deposition (CVD), physical vapor deposition (PVD), electroplating, or electroless plating. A protruding portion 72 is formed on the upper portion 54 of the adhesive 52 (FIG. 2D).

Then, a second groove 74 having a width d₂ smaller than the width d₁ of the first groove 62 is formed in the film 70 on the adhesive 52 formed in the first groove 62 from the side of the third surface 50c by, for example, blade dicing or laser dicing. As a result, a part of the protruding portion 72 of the film 70 formed on the first groove 62 is removed. From the protruding portion 72, the second portion 14 is formed. A portion of the film 70 in which the protruding portion 72 is not formed becomes the first portion 12 (FIG. 2E).

Then, a dicing tape (not shown) is attached so that the first portion 12 is in contact with the dicing tape, and then the substrate 60 is peeled off. Then, by peeling the adhesive 52 from the semiconductor substrate 50, the semiconductor device 100 of embodiments is obtained.

Next, the function and effect of embodiments will be described.

In the related art, the semiconductor substrate 50 and the film 70 are collectively processed using the same manufacturing process. However, in the case of processing using blade dicing, for example, there is a problem that the semiconductor substrate 50 is cracked at the timing when the processing stage is switched from the cutting of the semiconductor substrate 50 to the cutting of the film 70. In addition, in the case of processing using laser dicing, the electrically conductive material contained in the film 70 may adhere to the first side surface 2b of the semiconductor chip 2. Due to the electrically conductive material that adheres to the first side surface 2b of the semiconductor chip 2, there is a problem that the electrode 10 provided on the bottom surface 2a of the semiconductor device and an electrode (not shown in FIG. 1) provided on the top surface 2c are electrically connected to each other. In particular, in a semiconductor device in which the electrode 10 is thick, since the film 70 to be cut is thick, more electrically conductive materials are volatilized when the film 70 is cut. For this reason, the amount of the electrically conductive material adhering to the first side surface 2b also tends to increase. As a result, such a problem has become more serious.

Therefore, in the method of manufacturing a semiconductor device of embodiments, the first groove 62 that does not penetrate the semiconductor substrate 50 is formed in the semiconductor substrate 50 from the side of the first surface 50a of the semiconductor substrate 50 having the first surface 50a and the second surface 50b. In addition, a part of the semiconductor substrate 50 on the side of the second surface 50b is removed to expose the first groove 62, thereby forming the third surface 50c of the semiconductor substrate 50. In addition, a part of the film 70 formed adjacent to the first groove 62 is removed with a width d₂ smaller than the width d₁ of the first groove 62.

In the method of manufacturing a semiconductor device of embodiments, the dicing of the semiconductor substrate 50 and the dicing of the film 70 are performed separately in different steps. As a result, since the above-described problems can be avoided, it is possible to provide a semiconductor device with improved quality.

In addition, in the method of manufacturing a semiconductor device of embodiments, the adhesive 52 is applied to the first groove 62 so as to be filled up to the bottom portion 64 of the first groove 62. In addition, the adhesive 52 is applied to the first surface 50a. Then, a part of the semiconductor substrate 50 on the side of the second surface 50b is removed so that the first groove 62 and the third side surface 56 of the adhesive 52 are exposed. This manufacturing method is preferable for carrying out a manufacturing method in which the dicing of the semiconductor substrate 50 and the dicing of the film 70 are performed separately in different steps.

The semiconductor device of embodiments includes the semiconductor chip 2, which has the bottom surface 2a having the first area S₁ and the first side surface 2b, and the electrode 10, which is provided below the semiconductor chip 2, has the first top surface 13 which has the second area S₂ larger than the first area S₁ and at least a part of which is in contact with the bottom surface 2a, and contains an electrically conductive material.

For example, when dicing the semiconductor substrate 50 and the film 70 by blade dicing, it is difficult for the blade to spontaneously sharpen during the dicing of the film 70. For this reason, there is a problem that cracking or chipping occurs in the semiconductor substrate 50 and accordingly the mechanical strength or the reliability is lowered. However, as described above, according to the semiconductor device of embodiments, the dicing of the semiconductor substrate 50 and the dicing of the film 70 are performed separately in different steps, so that a high-quality semiconductor device can be provided.

In addition, when dicing the film 70 by laser dicing, unlike in the case of blade dicing, burrs are less likely to occur on the film 70. Such burrs can be an obstacle when the semiconductor device is picked up by, for example, an adsorption collet. However, according to the semiconductor device of embodiments, picking up is easy, so that it is unlikely that the semiconductor device will be dropped during picking up to cause damage to the inside of the semiconductor device, chip cracking, or the like. Therefore, it is possible to provide a high-quality semiconductor device.

Since the second area S₂ of the first top surface 13 of the electrode 10 is larger than the first area S₁ of the bottom surface 2a of the semiconductor chip 2, heat dissipation through the electrode 10 is high. In addition, since the second portion 14 provided diagonally downward with respect to the semiconductor chip 2 promotes heat dissipation from the second portion 14, the heat dissipation of the semiconductor chip 2 is further improved. Therefore, it is possible to provide a high-quality semiconductor device.

According to the semiconductor device and the method of manufacturing the same of embodiments, it is possible to provide a high-quality semiconductor device.

### Second Embodiment

A semiconductor device of embodiments is different from the semiconductor device of the first embodiment in that the electrode has a first portion in contact with a bottom surface and a third portion connected to the end of the first portion and in contact with the side surface. Here, the description of the content overlapping the first embodiment will be omitted.

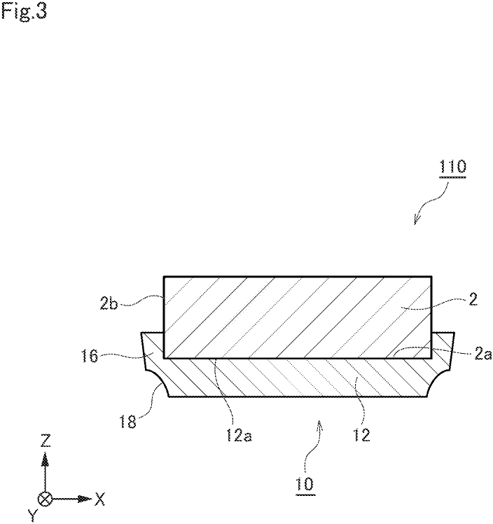

FIG. 3 is a schematic cross-sectional view of a semiconductor device 110 of embodiments.

An electrode 10 has a first portion 12 in contact with a bottom surface 2a and a third portion 16 connected to the end of the first portion 12 and in contact with a first side surface 2b. In addition, a first recessed portion 18 is provided at the end of the first portion 12.

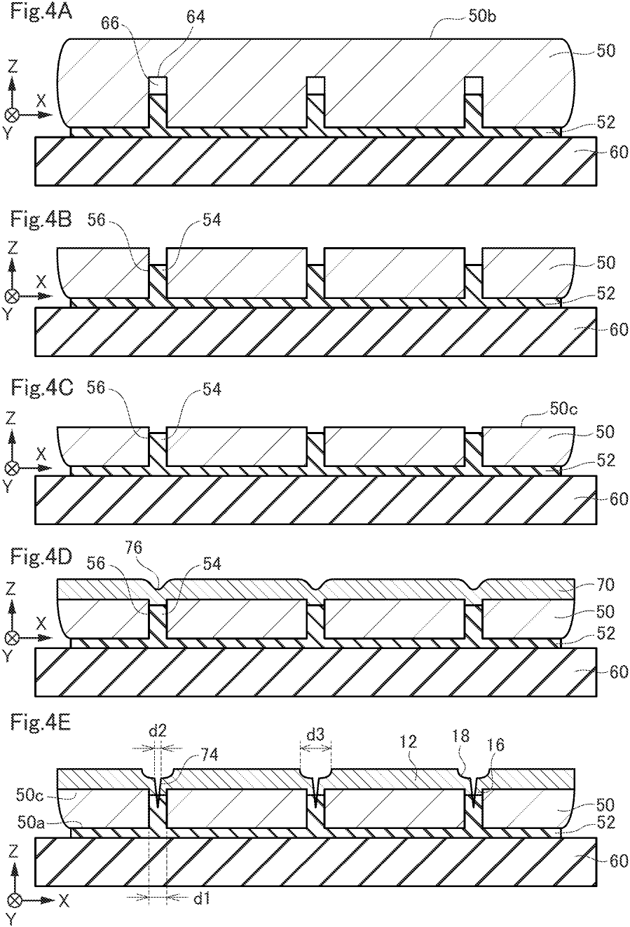

FIGS. 4A to 4E are schematic cross-sectional views showing a process of manufacturing the semiconductor device 110 of embodiments.

In embodiments, the adhesive 52 is applied to the first surface 50a and the first groove 62 so as not to be filled up to the bottom portion 64 of the first groove 62. Therefore, a gap 66 is formed in the bottom portion 64 of the first groove 62 (FIG. 4A).

Then, a part of the semiconductor substrate 50 on the side of the second surface 50b is removed by, for example, grinding to expose the first groove 62 (FIG. 4B). Then, a part of the semiconductor substrate 50 is removed by, for example, wet etching to form a third surface 50c on the semiconductor substrate 50. Here, a part of the third side surface 56 and the upper portion 54 of the adhesive 52 are not exposed (FIG. 4C) . The third surface 50c may be formed by grinding without performing wet etching.

Then, the film 70 containing an electrically conductive material is formed on the third surface 50c and the adhesive 52 by, for example, chemical vapor deposition (CVD), physical vapor deposition (PVD), electroplating, or electroless plating. A second recessed portion 76 is formed on (above) the upper portion 54 of the adhesive 52 (FIG. 4D).

Then, the second groove 74 having a width d₂ smaller than the width d₁ of the first groove 62 is formed in the film 70 on the adhesive 52 formed in the first groove 62 from the side of the third surface 50c by, for example, blade dicing or laser dicing. As a result, a part of the second recessed portion 76 of the film 70 formed on the first groove 62 is removed. A part of the film 70 formed so as to be in contact with the first groove 62 becomes the third portion 16. In addition, a part of the second recessed portion 76 becomes the first recessed portion 18 (FIG. 4E).

Since the electrode 10 has the first portion 12 in contact with the bottom surface 2a and the third portion 16 connected to the end of the first portion 12 and in contact with the first side surface 2b, heat dissipation from the third portion 16 is promoted. For this reason, the heat dissipation of the semiconductor chip 2 is further improved. Therefore, it is possible to provide a high-quality semiconductor device.

In addition, in the method of manufacturing a semiconductor device of embodiments, before removing a part of the semiconductor substrate 50 on the side of the second surface 50b so that the first groove 62 is exposed after forming the first groove 62 not penetrating the semiconductor substrate 50 in the semiconductor substrate 50 from the side of the first surface 50a of the semiconductor substrate 50 having the first surface 50a and the second surface 50b, the adhesive 52 is applied to the first surface 50a and the first groove 62 so as not to be filled up to the bottom portion of the first groove 62, the semiconductor substrate 50 having the first groove 62 is fixed to the substrate 60, and a part of the semiconductor substrate 50 on the side of the second surface 50b is removed so that the side surface of the adhesive 52 is not exposed. This manufacturing method is preferable for carrying out a manufacturing method in which the dicing of the semiconductor substrate 50 and the dicing of the film 70 are performed separately in different steps.

According to the semiconductor device and the method of manufacturing the same of embodiments, it is possible to provide a high-quality semiconductor device.

### Third Embodiment

A semiconductor device of embodiments is different from the semiconductor devices of the first and second embodiments in that the electrode has a portion protruding from the side surface in parallel with the bottom surface. Here, the description of the content overlapping the first and second embodiments will be omitted.

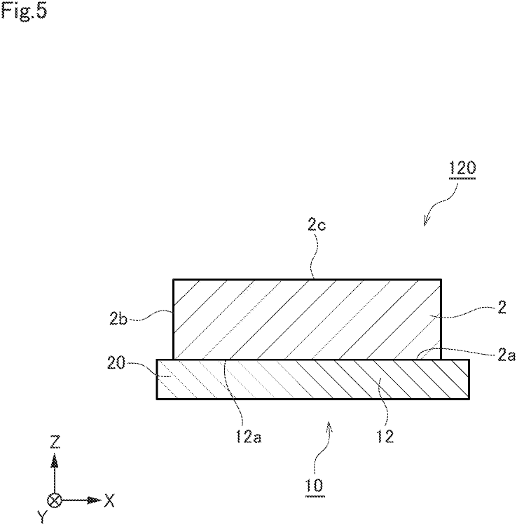

FIG. 5 is a schematic cross-sectional view of a semiconductor device 120 of embodiments. The electrode 10 has a fourth portion 20 protruding from the first side surface 2b of the semiconductor chip 2 in parallel with the bottom surface 2a of the semiconductor chip 2.

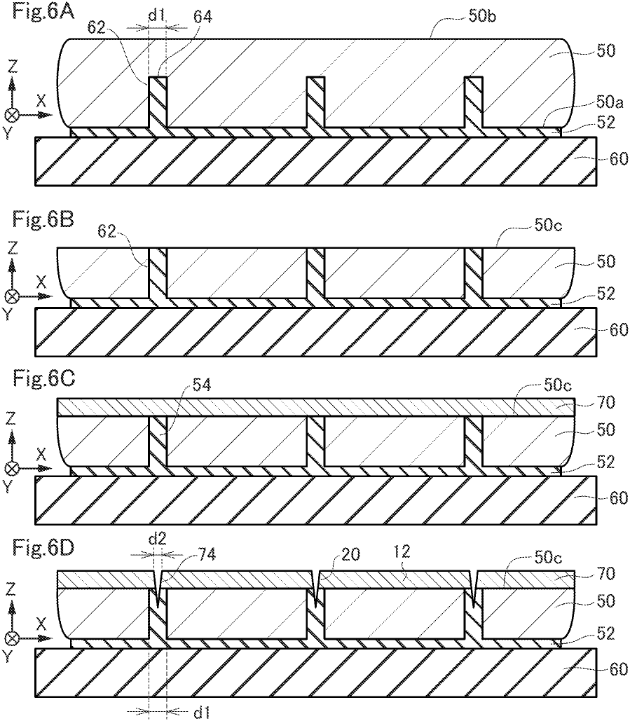

FIGS. 6A to 6D are schematic cross-sectional views showing a process of manufacturing the semiconductor device 120 of embodiments. The process of manufacturing the semiconductor device 120 of embodiments is the same as that of the first embodiment in that the semiconductor substrate 50 is fixed to the substrate 60 by using the adhesive 52 after the adhesive 52 is applied so as to be filled up to the bottom portion 64 of the first groove 62 (FIG. 6A).

Then, a part of the semiconductor substrate 50 on the side of the second surface 50b is removed by, for example, grinding to expose the first groove 62. Here, by proceeding to the next step for the film 70 without performing wet etching, the height of the adhesive 52 in the first groove 62 in the Z direction is made equal to the height of the third surface 50c (FIG. 6B).

Then, the film 70 containing an electrically conductive material is formed on the third surface 50c and the adhesive 52 by, for example, chemical vapor deposition (CVD), physical vapor deposition (PVD), electroplating, or electroless plating. The protruding portion 72 or the second recessed portion 76 is not formed on the upper portion 54 of the adhesive 52 (FIG. 6C).

Then, the second groove 74 having a width d₂ smaller than the width d₁ of the first groove 62 is formed in the film 70 on the adhesive 52 formed in the first groove 62 from the side of the third surface 50c by, for example, blade dicing or laser dicing. As a result, a part of the film 70 formed on the first groove 62 is removed. The film 70 on the adhesive 52 becomes the fourth portion 20 (FIG. 6D) .

Since the electrode 10 has the fourth portion 20 protruding from the first side surface 2b of the semiconductor chip in parallel with the bottom surface 2a, heat dissipation from the fourth portion 20 is promoted. For this reason, the heat dissipation of the semiconductor chip 2 is further improved. Therefore, it is possible to provide a high-quality semiconductor device.

In addition, in the method of manufacturing a semiconductor device of embodiments, a part of the semiconductor substrate 50 on the side of the second surface 50b is removed so that the side surfaces of the first groove 62 and the adhesive 52 are not exposed. This manufacturing method is preferable for carrying out a manufacturing method in which the dicing of the semiconductor substrate 50 and the dicing of the film 70 are performed separately in different steps.

According to the semiconductor device and the method of manufacturing the same of embodiments, it is possible to provide a high-quality semiconductor device.

### Fourth Embodiment

A semiconductor device of embodiments includes: a semiconductor chip having a bottom surface having a first area and a side surface; and an electrode provided below the semiconductor chip, having a top surface, and containing an electrically conductive material. The top surface has a second area smaller than the first area, and at least a part of the top surface is in contact with the bottom surface. Here, the description of the content overlapping the first to third embodiments will be omitted.

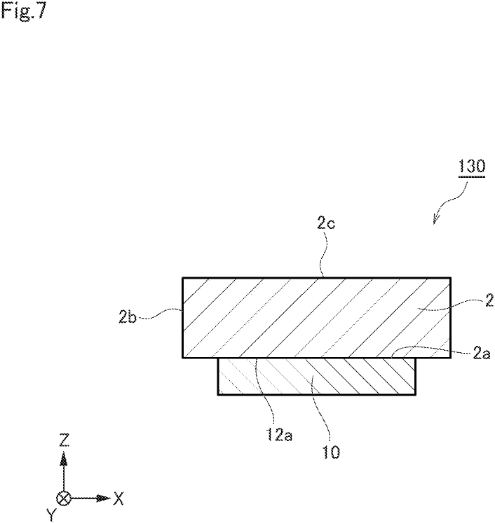

FIG. 7 is a schematic cross-sectional view of a semiconductor device 130 of embodiments. The second area S₂ of the top surface 12a of the electrode 10 is smaller than the first area S₁ of the bottom surface 2a of the semiconductor chip 2.

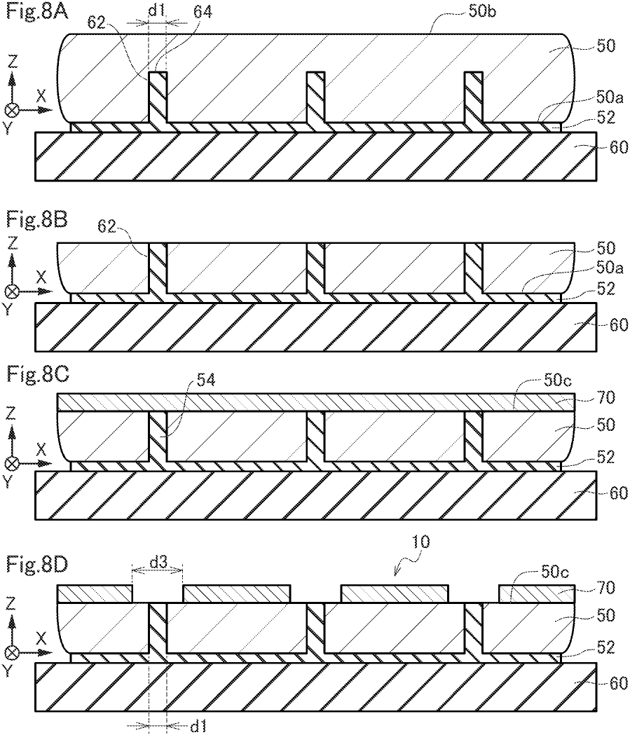

FIGS. 8A to 8D are schematic cross-sectional views showing a process of manufacturing the semiconductor device 130 of embodiments.

A method of manufacturing a semiconductor device of embodiments includes: forming a groove not penetrating a semiconductor substrate in the semiconductor substrate from a side of a first surface of the semiconductor substrate having the first surface and a second surface; forming a third surface of the semiconductor substrate by removing a part of the semiconductor substrate on a side of the second surface so that the groove is exposed; forming a film containing an electrically conductive material on the third surface; and removing a part of the film formed adjacent to the groove with a width larger than the width of the groove.

The method of manufacturing a semiconductor device of embodiments is the same as that of the first embodiment in that the semiconductor substrate 50 is fixed to the substrate 60 by using the adhesive 52 after the adhesive 52 is applied to the first surface 50a and the first groove 62 so as to be filled up to the bottom portion 64 of the first groove 62 (FIG. 8A).

Then, a part of the semiconductor substrate 50 on the side of the second surface 50b is removed by, for example, grinding so that the height of the adhesive 52 in the first groove 62 in the Z direction becomes equal to the height of the third surface 50c (FIG. 8B). Then, wet etching may be performed to expose the upper portion 54 of the adhesive 52.

Then, the film 70 containing an electrically conductive material is formed on the third surface 50c and the adhesive 52 by, for example, chemical vapor deposition (CVD), physical vapor deposition (PVD), electroplating, or electroless plating. The protruding portion 72 or the second recessed portion 76 is not formed on the upper portion 54 of the adhesive 52 (FIG. 8C).

Then, the second groove 74 having a width d₃ larger than the width d₁ of the first groove 62 is formed on the adhesive 52 formed in the first groove 62 from the side of the third surface 50c by, for example, blade dicing or laser dicing (FIG. 8D). The film 70 remaining on the third surface 50c becomes the electrode 10.

Also in the method of manufacturing a semiconductor device of embodiments, the dicing of the semiconductor substrate 50 and the dicing of the film 70 are performed separately in different steps. As a result, since the above-described problems can be avoided, it is possible to provide a semiconductor device with improved quality.

For example, when dicing the semiconductor substrate 50 and the film 70 by blade dicing, it is difficult for the blade to spontaneously sharpen during the dicing of the film 70. For this reason, there is a problem that cracking or chipping occurs in the semiconductor substrate 50 and accordingly the mechanical strength or the reliability is lowered. However, as described above, according to the semiconductor device of embodiments, the dicing of the semiconductor substrate 50 and the dicing of the film 70 are performed separately in different steps, so that a high-quality semiconductor device can be provided.

In addition, when dicing the film 70 by laser dicing, unlike in the case of blade dicing, burrs are less likely to occur on the film 70. Such burrs can be an obstacle when the semiconductor device is picked up by, for example, an adsorption collet. However, according to the semiconductor device of embodiments, picking up is easy, so that it is unlikely that the semiconductor device will be dropped during picking up to cause damage to the inside of the semiconductor device, chip cracking, or the like. Therefore, it is possible to provide a high-quality semiconductor device.

The second area S₂ of the top surface 12a of the electrode 10 is smaller than the first area S₁ of the bottom surface 2a of the semiconductor chip 2. Therefore, when the semiconductor device 100 is fixed to a pad or the like by using a die bonding agent or the like, the amount of the die bonding agent can be reduced. For this reason, a situation is unlikely to occur in which the die bonding agent crawls up to the first side surface 2b of the semiconductor chip 2 to cause poor conduction between the electrode 10 and an electrode (not shown in FIG. 7) provided on the top surface 2c.

According to the semiconductor device and the method of manufacturing the same of embodiments, it is possible to provide a high-quality semiconductor device.

### Fifth Embodiment

A semiconductor device of embodiments is different from the semiconductor device of the fourth embodiment in that a third recessed portion is provided at the end of the bottom surface of the semiconductor chip. Here, the description of the content overlapping the first to fourth embodiments will be omitted.

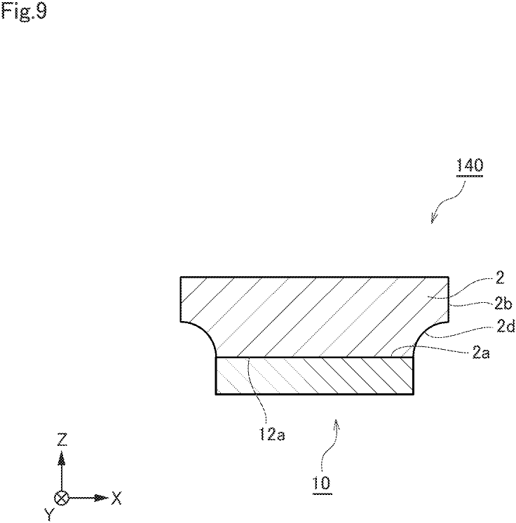

FIG. 9 is a schematic cross-sectional view of a semiconductor device 140 of embodiments. A third recessed portion 2d is provided at the end of the bottom surface 2a of the semiconductor chip.

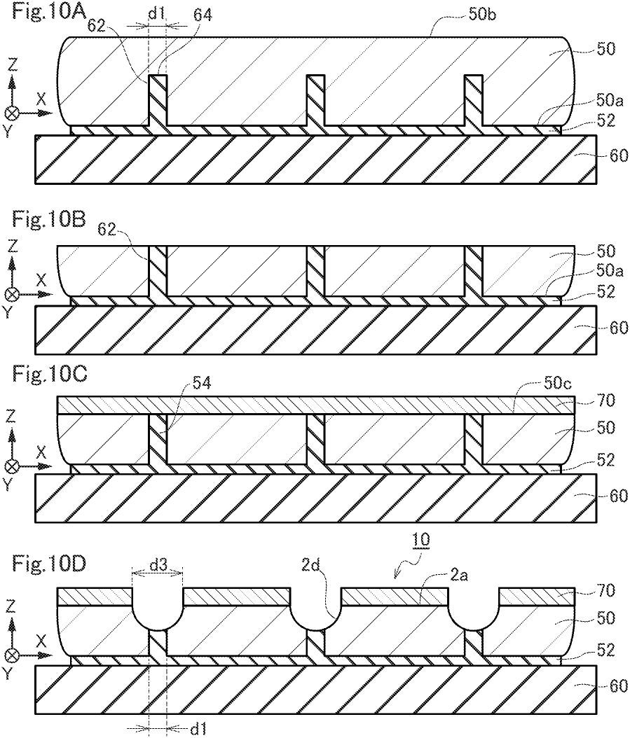

FIGS. 10A to 10D are schematic cross-sectional views of a method of manufacturing the semiconductor device 140 of embodiments. The method of manufacturing the semiconductor device 140 of embodiments is different from that of the fourth embodiment in that the third recessed portion 2d is formed when the second groove 74 having a width d₃ larger than the width d₁ of the first groove 62 is formed on the adhesive 52 formed in the first groove 62 from the side of the third surface 50c by, for example, blade dicing or laser dicing (FIG. 10D).

According to the semiconductor device and the method of manufacturing the same of embodiments, it is possible to provide a high-quality semiconductor device.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor chip having a bottom surface having a first area and a first side surface; and
an electrode provided below the semiconductor chip, the electrode having a first top surface and a second side surface, and the electrode containing an electrically conductive material,
wherein the first top surface has a second area larger than the first area, and at least a part of the first top surface is in contact with the bottom surface.

2. The semiconductor device according to claim 1,
wherein the electrode further includes:
a first portion having the second side surface and a second top surface in contact with the bottom surface; and
a second portion connected to an end of the first portion, the second portion being provided diagonally downward with respect to the semiconductor chip, and the second portion having a third top surface.

3. The semiconductor device according to claim 2, further comprising:
an adhesive in contact with the first side surface, the second side surface, and the third top surface.

4. The semiconductor device according to claim 1,
wherein the electrode includes:
a first portion in contact with the bottom surface; and
a third portion connected to an end of the first portion and in contact with the first side surface.

5. The semiconductor device according to claim 4,
wherein the electrode further includes a first recessed portion provided at the end of the first portion.

6. The semiconductor device according to claim 1,
wherein the electrode includes a fourth portion protruding from the first side surface in parallel with the bottom surface.

7. A semiconductor device, comprising:
a semiconductor chip having a bottom surface having a first area and a side surface; and
an electrode provided below the semiconductor chip, the electrode having a top surface, and the electrode containing an electrically conductive material,
wherein the top surface has a second area smaller than the first area, and at least a part of the top surface is in contact with the bottom surface.

8. The semiconductor device according to claim 7, further comprising:
a third recessed portion provided at an end of the bottom surface of the semiconductor chip.

9. A method of manufacturing a semiconductor device, comprising:
forming a groove not penetrating a semiconductor substrate in the semiconductor substrate from a side of a first surface of the semiconductor substrate having the first surface and a second surface;
forming a third surface of the semiconductor substrate by removing a part of the semiconductor substrate on a side of the second surface so that the groove is exposed;
forming a film containing an electrically conductive material on the third surface; and
removing a part of the film formed adjacent to the groove with a width smaller than a width of the groove.

10. The method of manufacturing a semiconductor device according to claim 9,
wherein, before removing a part of the semiconductor substrate on the side of the second surface so that the groove is exposed after forming the groove not penetrating the semiconductor substrate in the semiconductor substrate from the side of the first surface of the semiconductor substrate having the first surface and the second surface, an adhesive is applied to the first surface and the groove so as to be filled up to a bottom portion of the groove, and the semiconductor substrate having the groove is fixed to a substrate.

11. The method of manufacturing a semiconductor device according to claim 10,
wherein a part of the semiconductor substrate on the side of the second surface is removed so that the groove and a side surface of the adhesive are exposed.

12. The method of manufacturing a semiconductor device according to claim 11,
wherein a part of the semiconductor substrate on the side of the second surface is removed by grinding and wet etching.

13. The method of manufacturing a semiconductor device according to claim 12,
wherein the groove is exposed by the grinding, and the side surface of the adhesive is exposed by the wet etching.

14. The method of manufacturing a semiconductor device according to claim 10,
wherein a part of the semiconductor substrate on the side of the second surface is removed so that the groove and a side surface of the adhesive are not exposed.

15. The method of manufacturing a semiconductor device according to claim 9,
wherein, before removing a part of the semiconductor substrate on the side of the second surface so that the groove is exposed after forming the groove not penetrating the semiconductor substrate in the semiconductor substrate from the side of the first surface of the semiconductor substrate having the first surface and the second surface, an adhesive is applied to the first surface and the groove so as not to be filled up to a bottom portion of the groove, and the semiconductor substrate having the groove is fixed to a substrate, and
a part of the semiconductor substrate on the side of the second surface is removed so that a side surface of the adhesive is not exposed.

16. A method of manufacturing a semiconductor device, comprising:
forming a groove not penetrating a semiconductor substrate in the semiconductor substrate from a side of a first surface of the semiconductor substrate having the first surface and a second surface;
forming a third surface of the semiconductor substrate by removing a part of the semiconductor substrate on a side of the second surface so that the groove is exposed;
forming a film containing an electrically conductive material on the third surface; and
removing a part of the film formed adjacent to the groove with a width larger than a width of the groove.

17. The method of manufacturing a semiconductor device according to claim 16,
wherein a part of the film is removed by blade dicing.

18. The method of manufacturing a semiconductor device according to claim 16,
wherein a part of the film is removed by laser dicing.

19. The method of manufacturing a semiconductor device according to claim 16,
wherein, when a part of the film formed adjacent to the groove is removed with a width larger than a width of the groove, a third recessed portion is formed on the third surface.
